(19) United States
(12) Patent Application Publication
(10) Pub. No.: US 2022/0208873 A1
(43) Pub. Date: Jun. 30, 2022

(54) SPATIAL LIGHT-MODIFIED GRID TO ENHANCE DISPLAY EFFICIENCY

(71) Applicant: SHARP KABUSHIKI KAISHA, Sakai City (JP)

(72) Inventors: ANDREA ZAMPETTI, Abingdon (GB); VALERIE BERRYMAN-BOUSQUET, Chipping Norton (GB); TIM MICHAEL SMEETON, Oxford (GB)

(21) Appl. No.: 17/134,114

(22) Filed: Dec. 24, 2020

(51) Int. Cl. H01L 27/32; H01L 51/56; H01L 51/50

(52) U.S. Cl. CPC H01L 27/3218; H01L 27/3246; H01L 51/5072; H01L 51/5056; H01L 51/5092; H01L 51/56

(57) ABSTRACT

A light emitting device includes a sub-pixel region with a sub-pixel stack having a first electrode, second electrode, emissive layer between the first electrode and second electrode, a first charge transporting layer between the emissive layer and the first electrode, and a second charge transporting layer between the emissive layer and the second electrode. A bank in a bank region surrounds the sub-pixel stack. One of the first charge transporting or injecting layer and the second charge transporting or injecting layer is formed in the sub-pixel region and the bank region, and an electrical resistance of the first charge transporting layer and the second charge transporting layer in the bank region is higher than the sub-pixel region.

### FIELD

The present disclosure generally relates to light-emitting devices, and more particularly, to solution-processed devices such as organic light-emitting diodes (OLEDs) and quantum dot light-emitting diodes (QLEDs). The light-emitting devices may be used in display applications, for example, high resolution, multi-color displays. The present disclosure further relates to methods of manufacturing the light-emitting devices.

### BACKGROUND

A common architecture for a light-emitting device includes an anode and cathode; an emissive layer (EML) containing a material or a mixture of materials which emits light upon electron and hole recombination, such as an organic semiconductor layer or layer of quantum dots (QDs), and at least two charge transporting layers (CTLs); at least one hole transporting layer (HTL) between the anode and the emissive layer providing transport of holes from the anode and injection of holes into the emissive layer, and at least one electron transporting layer (ETL) between the cathode and the emissive layer providing transport of electrons from the cathode and injection of electrons into the emissive layer.

These layers are deposited on a substrate and it is possible to have different structures based on the order of deposition of the layers. In a standard structure the first layer deposited on the substrate is the anode, followed by the hole transporting layer, the emissive layer, the electron transporting layer and finally by the cathode. In an inverted structure, these layers are deposited on the substrate on the opposite order, starting with the cathode and finishing with the anode.

When the emissive layer includes an organic semiconductor material, the light-emitting device is referred to as an organic light emitting diode (OLED). When the emissive material includes nanoparticles, sometimes known as quantum dots (QDs), the device is referred to as either a quantum dot light emitting diode (QLED, QD-LED) or an electroluminescent quantum dot light emitting diode (ELQLED). For purposes of the present disclosure, the term LED is used to describe any of OLED, QLED, QD-LED.

Current deposition methods of solution processed OLEDS or QLEDs into regions or sub-pixels (e.g., on a substrate) aimed to fabricate red, green and blue (RGB) patterned LEDs for display application include various printing and stamping methods: inkjet, offset lithography, gravure, screen-printing, nano-imprinting, spin-coating, spray coating, UV-patterning and dip coating. The LEDs patterned into these regions or sub-pixels may be different respective EMLs such that they emit (through electrical injection, i.e., by electroluminescence) different respective colors (e.g., red (R), green (G), and blue (B)). Sub-pixels that respectively emit red, green, or blue light may collectively form a pixel, which in-turn may be a part of an array of pixels of the display.

However, several fabrication methods of solution-processed light-emitting devices may have only the emitting layer patterned, and the HTL and ETL are homogenously deposited across the display sub-pixels. These homogenously deposited ETL and HTL configurations may promote current leakage/cross talk effects across different sub-pixels. Current leakage or cross talking is here referred as the current percolating across the charge transporting layer rather to be injected to the emitting layer. This is mainly due to the lower resistance (or higher conductivity) of the CTL compared to the resistance at the interface of the CTL and the EML. This current loss not only affects device operation, but strongly affects display parameters, such as driving current and voltage and therefore efficiency and brightness.

Up to now, this issue has been addressed by disrupting the LED structure. For example, Peng Kuang-Chung et al. from Helix Technology in Taiwan patent no. JP2002151258A reported a method in which the substrate is etched to form a plurality of grooves, at bottom of which, positive electrodes are formed.

Kwang Ohk Cheon et al. from Apple Inc. in U.S. published application no. US20200035951A1 reported a method in which one of the thickness of at least one of the OLED layers may be reduced to reduce leakage current and cross-talk.

Parker Ian D. et al. from Uniax Corporation in U.S. published application no. US20020036291A1 reported a method in which the LED anode consists in multilayer anodes including a high conductivity organic layer adjacent to the EML and a low conductivity organic layer between the high conductivity organic layer and the anode's electrical connection layer. The multilayer anode structure provides sufficiently high resistivity to avoid cross-talk.

None of these references have exploited a spatial light-patterned grid to vary the resistance or conductivity of the CTLs. However, other references have investigated UV-light exposure for other purposes, such as LED patterning and coffee-ring effect hindering. Enrico Angioni et al. in U.S. patent no. U.S. Ser. No. 10/581,007B2 reported a method in which the emissive layer of a light-emitting device includes depositing a mixture including quantum dots and one or more crosslinkable charge transporting materials on a layer; and subjecting at least a portion of the mixture to UV activation to form an emissive layer including quantum dots dispersed in a crosslinked matrix.

LG Display Co. Ltd. in Korea patent no. KR1020150015139A reported a method in which a patterned surface tension across a pixelated bank structure via partial UV-exposure is used to alternate hydrophilic and hydrophobic HTL regions. The spatial surface energy modification promotes the confinement of the ink-jet printed emitting layer to hinder coffee-ring effect.

Steven A. Rutledge et al. from the University of Toronto in Etch-Free Patterning of Poly(3,4-ethylenedioxythiophene)-Poly(styrenesulfonate) for Optoelectronics, ACS Appl. Mater. Interfaces 2015, 7, 7, 3940-3948, reported a method in which an OLED with UV-patterned PEDOT:PSS. The regions of unexposed PEDOT:PSS produced electroluminescence, whereas those exposed to UV remained unlit, enabling the realization of pixelated illumination with no removal of materials.

### CITATION LIST

Japan Pat. No. JP2002151258A (Peng Kuang-Chung et al., Helix Technology, published May 24, 2002).
U.S. Pat. Pub. No. US20200035951A1 (Cheon et al., Apple Inc., published Jan. 30, 2020).
U.S. Pat. Pub. No. US20020036291A1 (Parker et al., Uniax Corporation, published Mar. 28, 2002).
U.S. patent Ser. No. 10/581,007B2 (Angioni et al., Sharp Kabushiki Kaisha, published Mar. 3, 2020).
Korea Pat. Pub. No. KR1020150015139A (LG Display Co. Ltd., published Feb. 10, 2015).
Etch-Free Patterning of Poly(3,4-ethylenedioxythiophene)-Poly(styrenesulfonate) for Optoelectronics (ACS Appl. Mater. Interfaces 2015, 7, 7, 3940-3948, by Steven A. Rutledge et al., the University of Toronto, doi.org/10.1021/am507981d).

### SUMMARY

A light emitting device includes a sub-pixel stack in a sub-pixel region, the sub-pixel stack having a first electrode, a second electrode, an emissive layer between the first electrode and the second electrode, a first charge transporting or injecting layer between the emissive layer and the first electrode, and a second charge transporting or injecting layer between the emissive layer and the second electrode. A bank in a bank region surrounds the sub-pixel stack.

At least one of the first charge transporting or injecting layer and the second charge transporting or injecting layer is formed in the sub-pixel region and the bank region, and an electrical resistance of the at least one of the first charge transporting or injecting layer and the second charge transporting or injecting layer in the bank region is higher than the sub-pixel region.

The first electrode may be an anode, and the first charge transporting or injecting layer a hole transporting or injecting layer. The second electrode may be a cathode, and the second charge transporting or injecting layer an electron transporting or injecting layer. Alternatively, the first electrode may be a cathode, and the first charge transporting or injecting layer an electron transporting or injecting layer, and the second electrode may be an anode, and the second charge transporting or injecting layer a hole transporting or injecting layer.

The at least one first charge transporting or injecting layer and the second charge transporting or injecting layer in the bank region may be exposed to light radiation (e.g., UV radiation) to increase the electrical resistance, while the at least one first charge transporting or injecting layer and the second charge transporting or injecting layer in the sub-pixel region is covered by a photomask. Alternatively, the at least one first charge transporting or injecting layer and the second charge transporting or injecting layer in the sub-pixel region may be exposed to light radiation (e.g., UV radiation) to reduce the electrical resistance, while the at least one first charge transporting or injecting layer and the second charge transporting or injecting layer in the bank region is covered by a photomask.

It should be appreciated that, while the present disclosure primarily describes UV radiation as a preferable light source, other wavelength ranges may be applied depending both on the light source and charge transporting material light response.

The emissive layer may be a solution-processed emissive layer having quantum dots. The at least one first charge transporting or injecting layer and the second charge transporting or injecting layer may comprise at least one organic semiconductor material having an amorphous or crystalline structure that is modifiable by light exposure (e.g., UV exposure), and the at least one first charge transporting or injecting layer and the second charge transporting or injecting layer may comprise metal-oxide nanoparticles.

In another implementation, a light emitting structure includes a substrate and a plurality of sub-pixel structures over the substrate, where at least one of the plurality of sub-pixel structures is formed in a sub-pixel region surrounded by a bank in a bank region, and the at least one of the plurality of sub-pixel structures includes a first electrode, a second electrode, an emissive layer between the first electrode and the second electrode a first charge transporting or injecting layer between the emissive layer and the first electrode and a second charge transporting or injecting layer between the emissive layer and the second electrode. At least one of the first charge transporting or injecting layer and the second charge transporting or injecting layer is formed in the sub-pixel region and the bank region, and an electrical resistance of the at least one of the first charge transporting or injecting layer and the second charge transporting or injecting layer in the bank region is preferably higher than the sub-pixel region.

The first electrode may be an anode, and the first charge transporting or injecting layer a hole transporting or injecting layer. The second electrode may be a cathode, and the second charge transporting or injecting layer an electron transporting or injecting layer. The first electrode may be a cathode, and the first charge transporting or injecting layer an electron transporting or injecting layer. The second electrode may be an anode, and the second charge transporting or injecting layer a hole transporting or injecting layer.

The at least one of the first charge transporting or injecting layer and the second charge transporting or injecting layer in the bank region may be exposed to light radiation (e.g., UV radiation) to increase the electrical resistance, while the at least one of the first charge transporting or injecting layer and the second charge transporting or injecting layer in the sub-pixel region is covered by a photomask. The light radiation may be delimited by the photomask to create a light-spatial modified grid to reduce current leakage across the sub-pixel regions. Alternatively, the at least one of the first charge transporting or injecting layer and the second charge transporting or injecting layer in the sub-pixel region may be exposed to light radiation (e.g., UV radiation) to reduce the electrical resistance, while the at least one of the first charge transporting or injecting layer and the second charge transporting or injecting layer in the bank region is covered by a photomask. The light radiation (e.g., UV radiation) is delimited by the photomask to create a light-spatial modified grid to reduce current leakage across the sub-pixel regions.

The at least one of the first charge transporting or injecting layer and the second charge transporting or injecting layer may comprise at least one organic semiconductor material having an amorphous or crystalline structure that is modifiable by light exposure.

### BRIEF DESCRIPTION OF THE DRAWINGS

Aspects of the exemplary disclosure are best understood from the following detailed description when read with the accompanying figures. Various features are not drawn to scale, dimensions of various features may be arbitrarily increased or reduced for clarity of discussion.

FIG. 1 illustrates a schematic cross-sectional view of a related art light-emitting device.

FIG. 2 illustrates a flowchart illustrating an exemplary fabrication method for a light emitting structure in accordance with an implementation of the present disclosure.

FIG. 3A illustrates a schematic cross-sectional view of a portion of an example light emitting structure processed in accordance with an action in the flowchart of FIG. 2.

FIG. 3B illustrates a schematic cross-sectional view of a portion of an example light emitting structure processed in accordance with an action in the flowchart of FIG. 2.

FIG. 3C illustrates a schematic cross-sectional view of a portion of an example light emitting structure processed in accordance with an action in the flowchart of FIG. 2.

FIG. 3D illustrates a schematic cross-sectional view of a portion of an example light emitting structure processed in accordance with an action in the flowchart of FIG. 2.

FIG. 3E illustrates a schematic cross-sectional view of a portion of an example light emitting structure processed in accordance with an action in the flowchart of FIG. 2.

FIG. 3F illustrates a schematic cross-sectional view of a portion of an example light emitting structure processed in accordance with an action in the flowchart of FIG. 2.

FIG. 3G illustrates a schematic cross-sectional view of a portion of an example light emitting structure processed in accordance with an action in the flowchart of FIG. 2.

FIG. 3H illustrates a schematic cross-sectional view of a portion of an example light emitting structure processed in accordance with an action in the flowchart of FIG. 2.

FIG. 4A illustrates a schematic cross-sectional view of a portion of an example light emitting structure processed in accordance with an action in the flowchart of FIG. 2.

FIG. 4B illustrates a schematic cross-sectional view of a portion of an example light emitting structure processed in accordance with an action in the flowchart of FIG. 2.

FIG. 4C illustrates a schematic cross-sectional view of a portion of an example light emitting structure processed in accordance with an action in the flowchart of FIG. 2.

FIG. 4D illustrates a schematic cross-sectional view of a portion of an example light emitting structure processed in accordance with an action in the flowchart of FIG. 2.

FIG. 4E illustrates a schematic cross-sectional view of a portion of an example light emitting structure processed in accordance with an action in the flowchart of FIG. 2.

FIG. 4F illustrates a schematic cross-sectional view of a portion of an example light emitting structure processed in accordance with an action in the flowchart of FIG. 2.

FIG. 4G illustrates a schematic cross-sectional view of a portion of an example light emitting structure processed in accordance with an action in the flowchart of FIG. 2.

FIG. 4H illustrates a schematic cross-sectional view of a portion of an example light emitting structure processed in accordance with an action in the flowchart of FIG. 2.

FIG. 5A illustrates a schematic cross-sectional view of a portion of an example light emitting structure processed in accordance with an action in the flowchart of FIG. 2.

FIG. 5B illustrates a schematic cross-sectional view of a portion of an example light emitting structure processed in accordance with an action in the flowchart of FIG. 2.

FIG. 5C illustrates a schematic cross-sectional view of a portion of an example light emitting structure processed in accordance with an action in the flowchart of FIG. 2.

FIG. 5D illustrates a schematic cross-sectional view of a portion of an example light emitting structure processed in accordance with an action in the flowchart of FIG. 2.

FIG. 5E illustrates a schematic cross-sectional view of a portion of an example light emitting structure processed in accordance with an action in the flowchart of FIG. 2.

FIG. 5F illustrates a schematic cross-sectional view of a portion of an example light emitting structure processed in accordance with an action in the flowchart of FIG. 2.

FIG. 5G illustrates a schematic cross-sectional view of a portion of an example light emitting structure processed in accordance with an action in the flowchart of FIG. 2.

FIG. 5H illustrates a schematic cross-sectional view of a portion of an example light emitting structure processed in accordance with an action in the flowchart of FIG. 2.

FIG. 6A illustrates a schematic cross-sectional view of a portion of an example light emitting structure processed in accordance with an action in the flowchart of FIG. 2.

FIG. 6B illustrates a schematic cross-sectional view of a portion of an example light emitting structure processed in accordance with an action in the flowchart of FIG. 2.

FIG. 6C illustrates a schematic cross-sectional view of a portion of an example light emitting structure processed in accordance with an action in the flowchart of FIG. 2.

FIG. 6D illustrates a schematic cross-sectional view of a portion of an example light emitting structure processed in accordance with an action in the flowchart of FIG. 2.

FIG. 6E illustrates a schematic cross-sectional view of a portion of an example light emitting structure processed in accordance with an action in the flowchart of FIG. 2.

FIG. 6F illustrates a schematic cross-sectional view of a portion of an example light emitting structure processed in accordance with an action in the flowchart of FIG. 2.

FIG. 6G illustrates a schematic cross-sectional view of a portion of an example light emitting structure processed in accordance with an action in the flowchart of FIG. 2.

FIG. 7 illustrates a schematic cross-sectional view of a portion of an example light emitting structure processed in accordance with an action in the flowchart of FIG. 2.

FIG. 8 illustrates a schematic cross-sectional view of a portion of an example light emitting structure processed in accordance with an action in the flowchart of FIG. 2.

### DESCRIPTION

The following description contains specific information pertaining to exemplary implementations of the present disclosure. The drawings in the present disclosure and their accompanying detailed description are directed to merely exemplary implementations. However, the present disclosure is not limited to merely these exemplary implementations. Other variations and implementations of the present disclosure will occur to those skilled in the art. Unless noted otherwise, like or corresponding elements among the figures may be indicated by like or corresponding reference numerals. Moreover, the drawings and illustrations in the present disclosure are generally not to scale, and are not intended to correspond to actual relative dimensions.

For consistency and ease of understanding, like features are identified (although, in some examples, not shown) by numerals in the exemplary figures. However, the features in different implementations may differ in other aspects, and thus shall not be narrowly confined to what is shown in the figures.

The phrases “in one implementation,” or “in some implementations,” may each refer to one or more of the same or different implementations. The term “coupled” is defined as connected, whether directly or indirectly through intervening components, and is not necessarily limited to physical connections. The term “comprising,” when utilized, means “including, but not necessarily limited to”; it specifically indicates an open-ended inclusion or membership in the so-described combination, group, series and the equivalent.

Disclosed is a high-resolution pattern of light-emitting devices having different respective configurations of emissive regions, which are capable of producing different colors (e.g. RGB). Exemplary fabrication methods are disclosed which may provide the high-resolution patterning of these light-emitting devices.

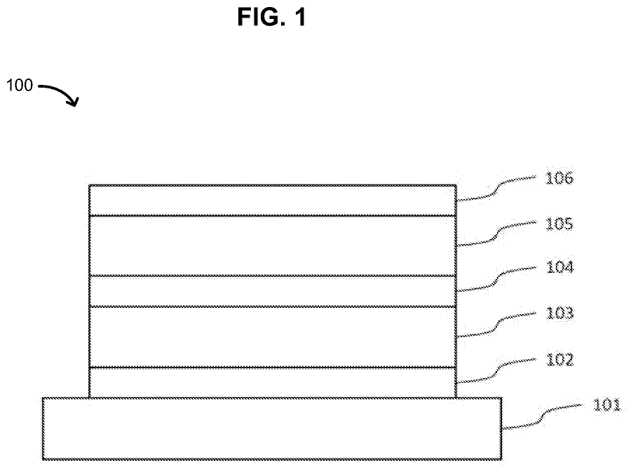

In FIG. 1, a related art light emitting device (LED) is indicated generally by reference 100. LEDs may consist of a substrate 101, a first electrode 102, a first charge transporting layer (CTL) 103, an emitting layer (EML) 104, a second CTL 105 and a second electrode 106. Additional layers may be present between the first electrode 102, the second electrode 106, and the EML 104, such as one or more charge injection layers, additional CTLs and charge blocking layers (not shown).

In a direct (also called a “non-inverted”) LED structure, the electrode closest to the substrate (e.g., the first electrode 102 in the illustrated implementation) is an anode, and any layers (e.g., the first CTL 103) between the first electrode 102 and the EML 104 are hole transporting layers (HTLs), hole injecting layers (HILs) or electron blocking layers (EBLs). Similarly, the electrode furthest from the substrate (second electrode 106 in the illustrated implementation) is a cathode, and any layers (e.g., the second CTL 105) between the second electrode 106 and the EML 104 are ETLs, electron injecting layers (EILs) or hole blocking layers (HBLs). In an inverted LED structure, the positions of these structures—anode and cathode, along with all injection, transporting and blocking layers—is reversed.

When an electrical bias is applied to the LED 100, holes are transported from the anode (e.g., the first electrode 102 or second electrode 106, depending on direct or inverted structure) and injected into the EML 104, and electrons are conducted from the cathode (first electrode 102, or second electrode 106, depending on direct or inverted structure) and injected into the EML 104. The holes and electrons recombine in either an organic semiconductor material or quantum dots in the EML 104, generating light. Some of this light is emitted out of the LED 100 where it may be perceived by an external viewer, together, the LEDs forming an LED array. Light may be emitted through the substrate 101, in which case the device is called “bottom-emitting”, or opposite the substrate 101, in which case the device is called “top-emitting”.

To form a multi-color display, three different types of LEDs with different EMLs 104 should be deposited on three different regions of a substrate, such that each region emits light (through electrical injection; i.e. by electroluminescence) in three different colors, particularly red (R), green (G) and blue (B) (collectively, RGB). These three different regions form a sub-pixel that respectively emit red, green, and blue light, collectively form a pixel, which in turn may be a part of an array of pixels in the display.

To achieve the required RGB configuration for a multi-color display application, LEDs may be arranged such that the LEDs are separated at least in part by one or more bank structures having insulating materials.

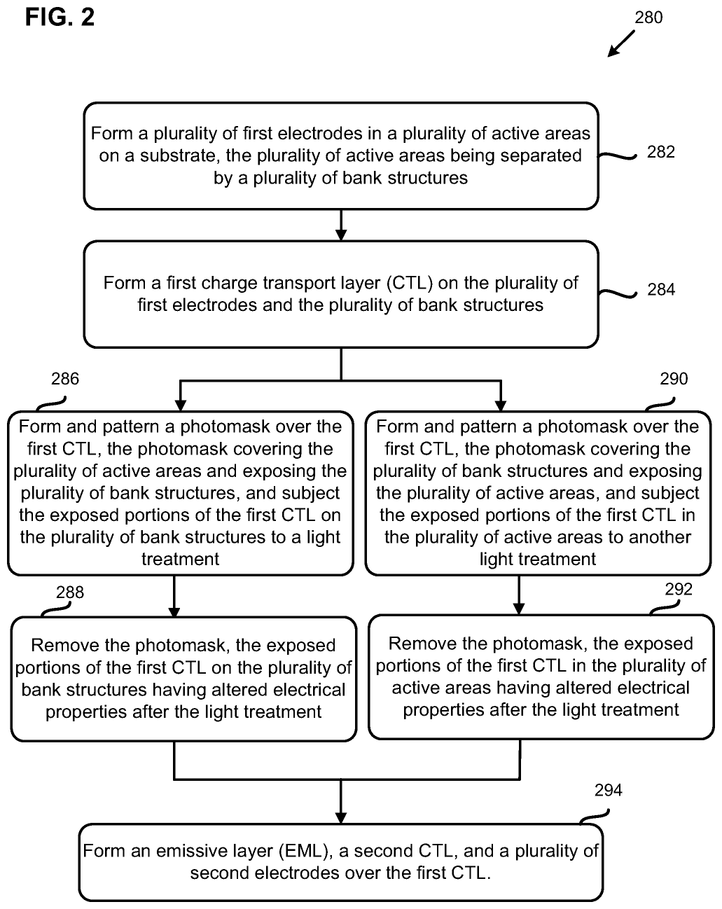

FIG. 2 shows a flowchart illustrating a method for fabricating an example light emitting structure in accordance with an implementation of the present disclosure. Certain details and features have been left out of the flowchart that are apparent to a person of ordinary skill in the art. For example, an action may consist of one or more sub-actions or may involve specialized equipment or materials, as known in the art. As illustrated in FIG. 2, actions 282, 284, 286, 288, 290, 292, and 294 indicated in the flowchart 280 are sufficient to describe one implementation of the present disclosure, other implementations of the present disclosure may utilize actions different from those shown in the flowchart.

In the flowchart 280, action 282 includes forming a plurality of first electrodes in a plurality of sub-pixel areas on a substrate, the plurality of sub-pixel areas being separated by a plurality of bank structures. Action 284 includes forming a first charge transporting layer (CTL) (or a first charge injecting layer) on the plurality of first electrodes and the plurality of bank structures. It should be understood that references to a charge transporting layer, as discussed in the following implementations, contemplate the use of a charge injecting layer in the alternative.

Action 286 includes forming and patterning a photomask over the first CTL, the photomask covering the plurality of sub-pixel areas and exposing the plurality of bank structures (e.g., the top portions of the plurality of bank structures), and subjecting the exposed portions of the first CTL on the plurality of bank structures to a light treatment (e.g., a UV treatment). Action 288 includes removing the photomask. As a result of the light treatment, the exposed portions of the first CTL on the plurality of bank structures has altered electrical properties. For example, the portions of the first CTL on the top edges of the plurality of bank structures have an increased resistance as compared to the portions of the first CTL in the sub-pixel areas that were covered by the photomask during the light treatment.

In the alternative or in addition to actions 286 and 288, the flowchart 280 also includes actions 290 and 292. Action 290 includes forming and patterning a photomask over the first CTL, the photomask covering the plurality of bank structures (e.g., the top portions of the plurality of bank structures) and exposing the plurality of sub-pixel areas, and subjecting the exposed portions of the first CTL in the exposed plurality of sub-pixel areas to another light treatment (e.g., another UV treatment).

Action 292 includes removing the photomask. As a result of the light treatment, the exposed portions of the first CTL in the plurality of sub-pixel areas have altered electrical properties. For example, the portions of the first CTL in the plurality of sub-pixel areas have an increased conductivity as compared to the portions of the first CTL on the plurality of bank structures covered by the photomask during the light treatment.

In the flowchart 280, action 294 includes forming an emissive layer (EML), a second CTL, and a plurality of second electrodes over the first CTL.

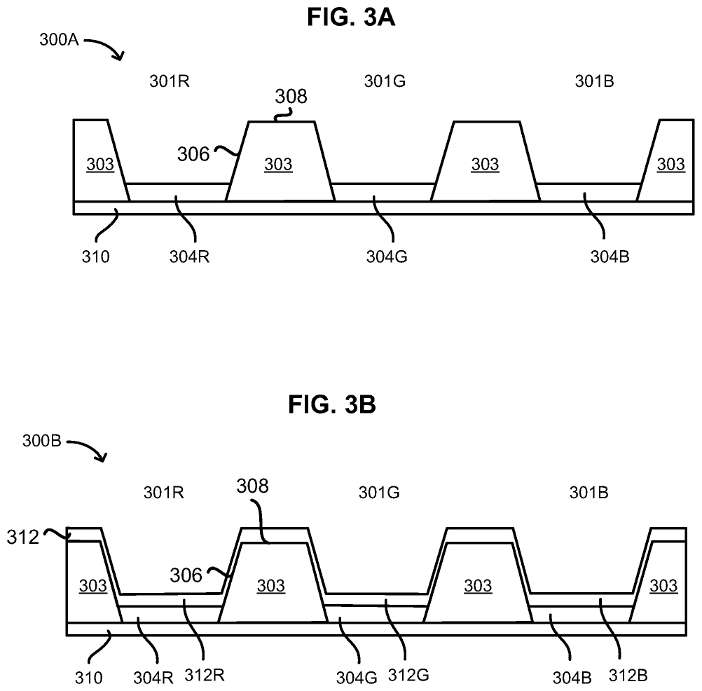

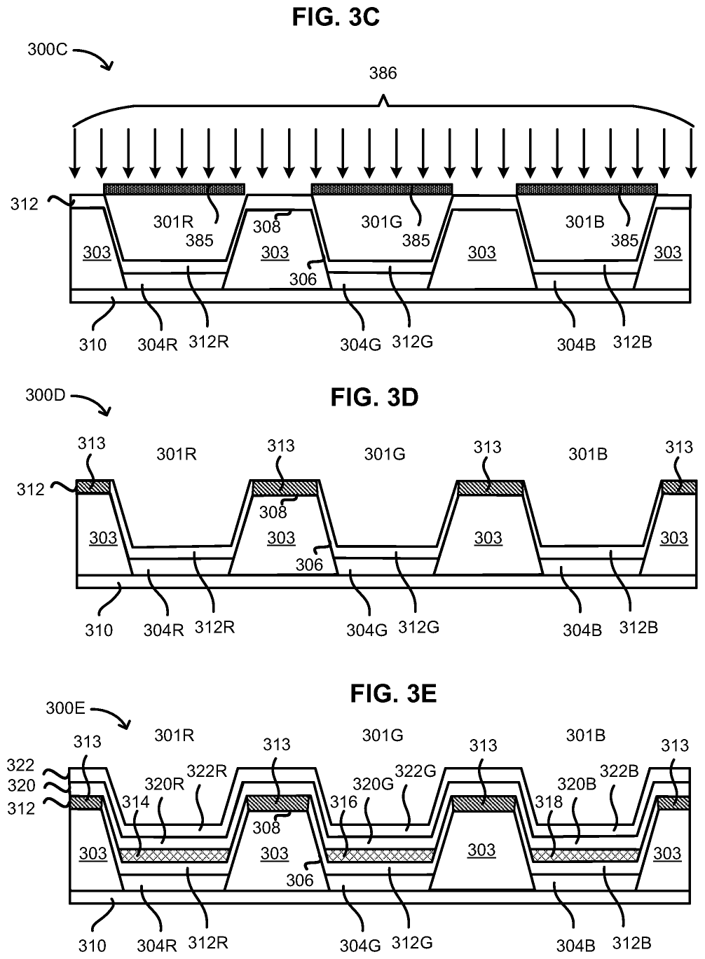

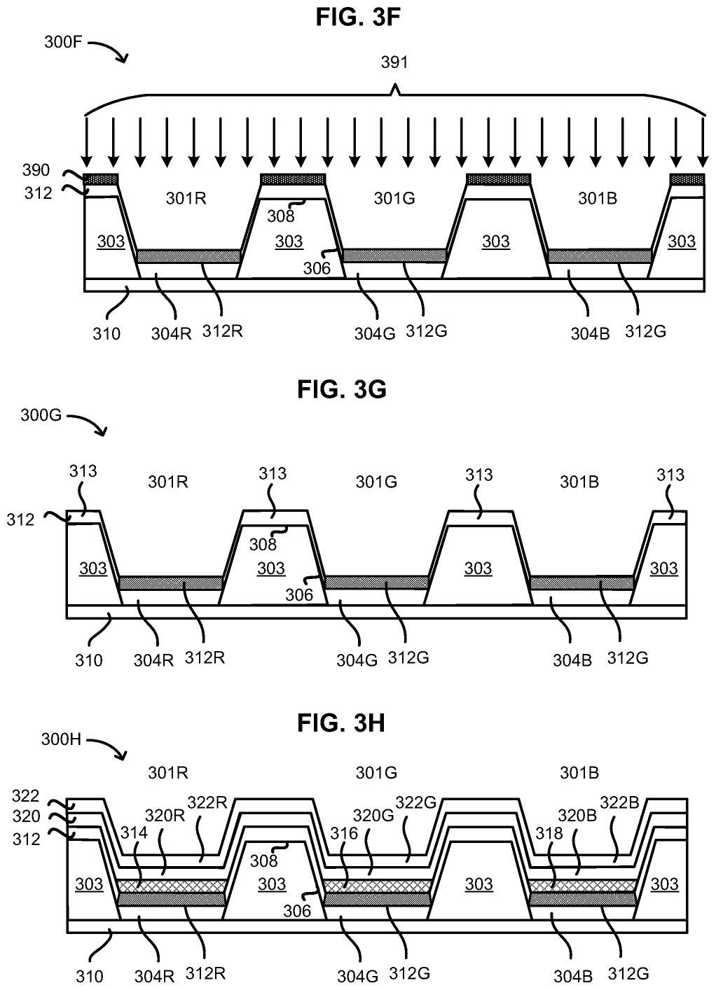

FIGS. 3A through 3H illustrate example light emitting structures 300A through 300H, respectively, processed in accordance with the actions described in the flowchart 280 of FIG. 2.

In the example light emitting structure 300A in FIG. 3A, first electrodes 304R, 304G, and 304B are formed (e.g., deposited) in sub-pixel areas 301R, 301G, and 301B, respectively, on a substrate 310, where the sub-pixel areas 301R, 301G, and 301B are separated by bank structures 303. In the illustrated implementation, the three sub-pixel areas 301R, 301G, and 301B are used to distinguish between three different color RGB (e.g., red, green, and blue) sub-pixels. It should be understood that a display device according implementations of the present disclosure may include a two-dimensional array of the pixels each having the RGB sub-pixels.

The first electrodes 304R, 304G, and 304B may each include the same material in the three sub-pixel areas or a different material for each sub-pixel area, and may or may not have the same thickness. The bank structures 303 include insulating materials, and are shaped to accommodate three different sub-pixels (e.g., LEDs) in the sub-pixel areas 301R, 301G, and 301B. In the present implementation, each of the bank structures 303 includes sidewalls 306 and a top portion 308.

In the example light emitting structure 300B in FIG. 3B, a first CTL 312 is formed (deposited) over the light emitting structure 300A shown in FIG. 3A. In the present implementation, the first CTL 312 is a continuous layer covering the bank structures 303 as well as the first electrodes 304R, 304G, and 304B. As shown in FIG. 3B, in each of the sub-pixel areas 301R, 301G, and 301B, a portion (e.g., portion 312R, 312G, or 312B) of the first CTL 312 is formed over the corresponding one of the first electrodes 304R, 304G, and 304B. The first CTL 312 is also formed on the sidewalls 306 and the top portion 308 of each of the bank structures 303.

In the example light emitting structure 300C in FIG. 3C, a patterned photomask (e.g., a shadow mask) 385 is formed over portions of the first CTL 312. The patterned photomask 385 covers the sub-pixel areas 301R, 301G, and 301B, and exposes portions of the first CTL 312 on the top portions 308 of the bank structures 303. While the patterned photomask 385 is in place, the light emitting structure 300C undergoes a light treatment (e.g., a UV treatment), where the exposed portions of the first CTL 312 on the top portions 308 of the bank structures 303 receive light radiation 386 (e.g., UV radiation).

In the example light emitting structure 300D in FIG. 3D, the patterned photomask 385 is removed. As a result of the light treatment, the exposed portions 313 of the first CTL 312 on the bank structures 303 have altered charge transporting (or injecting) properties (e.g., electrical conductivity or sheet-resistance), while the charge transporting (or injecting) properties of the portions of the first CTL 312 covered by the patterned photomask 385 remain unaffected by the light treatment. For example, the exposed portions 313 of the first CTL 312 on the top portions 308 of the bank structures 303 have an increased sheet-resistance (or reduced electrical conductivity) as compared to the portions 312R, 312G, and 312B of the first CTL 312 in the sub-pixel areas 301R, 301G, and 301B, respectively, that were covered by the patterned photomask 385 during the light treatment.

In the example light emitting structure 300E in FIG. 3E, EMLs 314, 316, and 318 are formed over the portions 312R, 312G, and 312B of the first CTL 312, respectively. The EMLs 314, 316, and 318, in one implementation, may constitute different organic semiconductor layers or QD layers in order to create an RGB array for multi-color displays, and may or may not have the same thickness. A second CTL 320 is formed over the EMLs 314, 316, and 318. The second CTL 320 may be a continuous layer covering the bank structures 303 as well as the sub-pixel areas 301R, 301G, and 301B. In addition, a second electrode layer 322 (e.g., having second electrodes 322R, 322G, and 322B) is formed over the second CTL 320 thus creating three completed LED sub-pixels in the light emitting structure 300E. In the light emitting structure 300E shown in FIG. 3E, the first CTL 312 on the bank structures 303 were treated with the light radiation 386 (FIG. 3C) thereby having altered charge transporting properties.

In the example light emitting structure 300F in FIG. 3F, instead of forming the patterned photomask 385 over the sub-pixel areas 301R, 301G, and 301B as shown in FIG. 3C, a patterned photomask (e.g., a shadow mask) 390 is formed over the first CTL 312. The patterned photomask 390 covers portions of the first CTL 312 on the top portions 308 of the bank structures 303, and exposes portions of the first CTL 312 (e.g., e.g., the portions 312R, 312G, and 312B) in the sub-pixel areas 301R, 301G, and 301B. While the patterned photomask 390 is in place, the light emitting structure 300F undergoes a light treatment (e.g., a UV treatment), where the exposed portions of the first CTL 312 in the sub-pixel areas 301R, 301G, and 301B receive light radiation 391 (e.g., UV radiation).

In the example light emitting structure 300G in FIG. 3G, the patterned photomask 390 is removed. As a result of the light treatment, the exposed portions 312R, 312G, and 312B of the first CTL 312 in the sub-pixel areas 301R, 301G, and 301B, respectively, have altered charge transporting properties, while the charge transporting properties of the portions of the first CTL 312 covered by the patterned photomask 390 remain unaffected by the light treatment. For example, the portions 312R, 312G, and 312B of the first CTL 312 in the sub-pixel areas 301R, 301G, and 301B, respectively, have an increased electrical conductivity (or reduced sheet-resistance) as compared to the portions 313 of the first CTL 312 on the top portions 308 of the bank structures 303 that were covered by the patterned photomask 390 during the light treatment.

In the example light emitting structure 300H in FIG. 3H, the EMLs 314, 316, and 318 are formed over the portions 312R, 312G, and 312B of the first CTL 312, respectively. The EMLs 314, 316, and 318, in one implementation, may constitute different organic semiconductor layers or QD layers in order to create an RGB array for multi-color displays. Also, a second CTL 320 and a plurality of second electrodes 322 are formed over the EMLs 314, 316, and 318. The second CTL 320 may be a continuous layer covering the bank structures 303 as well as the sub-pixel areas 301R, 301G, and 301B. In addition, a second electrode layer 322 is formed over the second CTL 320 thus creating three completed LED sub-pixels in the light emitting structure 300H. In various implementations, the second electrode layer 322 may be formed of multiple layers, and these layers may or may not all be continuous. In the light emitting structure 300H shown in FIG. 3H, the first CTL 312 in the sub-pixel areas 301R, 301G, and 301B were treated with light radiation 391 (FIG. 3F) thereby having altered charge transporting properties.

With respect to FIGS. 3A and 3H, it should be understood that the first electrodes 304R, 304G, and 304B may comprise the same material, and may or may not have the same thickness. Likewise, the portions 312R, 312G, and 312B of the first CTL 312 may comprise the same material. Similarly, referring to FIGS. 3E and 3H, different portions of the second CTL 320 may comprise the same material, as with the second electrode layer 322.

With respect to FIGS. 3E and 3H, as discussed above, in a preferred implementation, the EMLs 314, 316, and 318 may comprise different organic semiconductor layers or QD layers in order to generate an RGB multi-color display. However, in another implementation, the EMLs 314, 316, and 318 may comprise the same material, and may or may not have the same thickness.

In each of FIGS. 3A through 3H, the thickness of individual layers is preferably in the range of 1 to 150 nm. Additionally, the light radiations 386 and 391 to the first CTL (e.g., the first CTL 312) may be different depending on the CTL materials used, and the characteristics of those materials, such as photochemical response to UV-light.

In one implementation, after treatment with the light radiations 386 and/or 391, the electrical conductivity (or sheet resistance) of the first CTL 312 is lower (or higher, related to the sheet resistance) on the portions 313 of the bank structures 303 than in the sub-pixel areas 301R, 301G, and 301B. The lower electrical conductivity (or higher sheet resistance) of the first CTL 312 over the bank structures 303 prevents leakage (or cross-talking) across adjacent sub-pixels of the current percolating across the first CTL 312.

The present method may be applied to a direct LED structure, where the first electrodes 304R, 304G, and 304B are anode electrodes, the portions 312R, 312G, and 312B of the first CTL 312 may each include a hole transporting layer (HTL), a hole injecting layer (HIL) and/or an electron blocking layers (EBL). The portions 320R, 320G, and 320B of the second CTL 320 may each include an electron transporting layer (ETL), an electron injecting layer (EIL) and/or a hole blocking layer (HBL). The second electrode layer 322 is a cathode electrode layer.

The present method may also be applied to an inverted LED structure, where the first electrodes 304R, 304G, and 304B are cathode electrodes, the portions 312R, 312G, and 312B of the first CTL 312 may each include an ETL, an EIL and/or an HBL. The portions 320R, 320G, and 320B of the second CTL 320 may each include an HTL, an HIL, and/or an EBL. The second electrode layer 322 is an anode electrode layer.

Light exposures (e.g., UV-radiation exposures) may be carried out on the bank structures 303 (including the top portions 308), and/or in the sub-pixel areas 301R, 301G, and 301B based on the light response of a particular CTL material used. The light exposures to the first CTL 312 may disrupt the planar conductivity of the first CTL 312 between the RGB sub-pixels thereby substantially eliminating current leakage/cross talk across different sub-pixels.

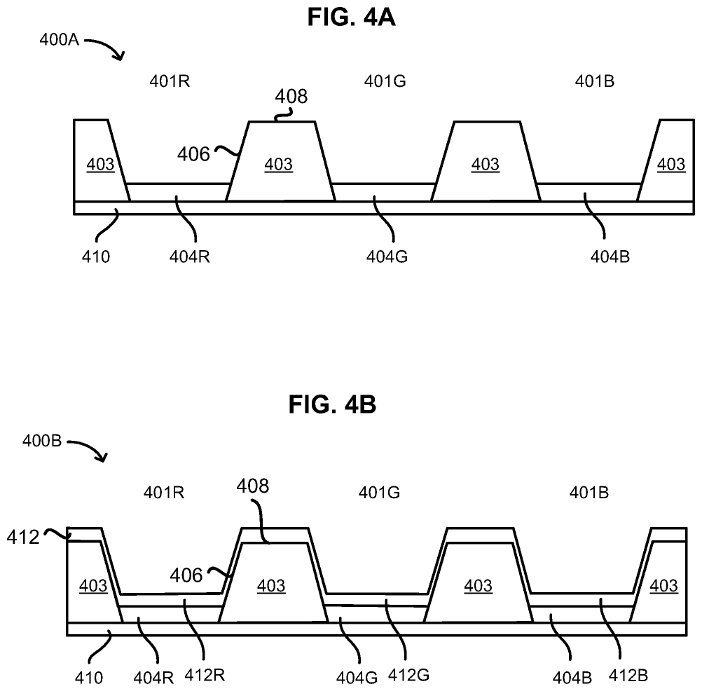

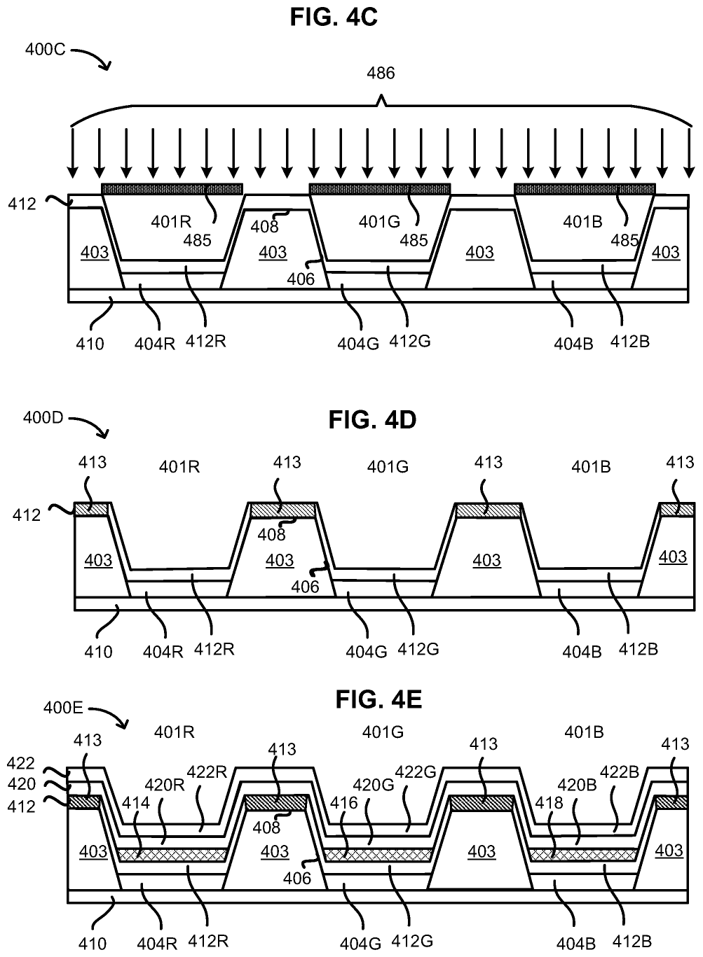

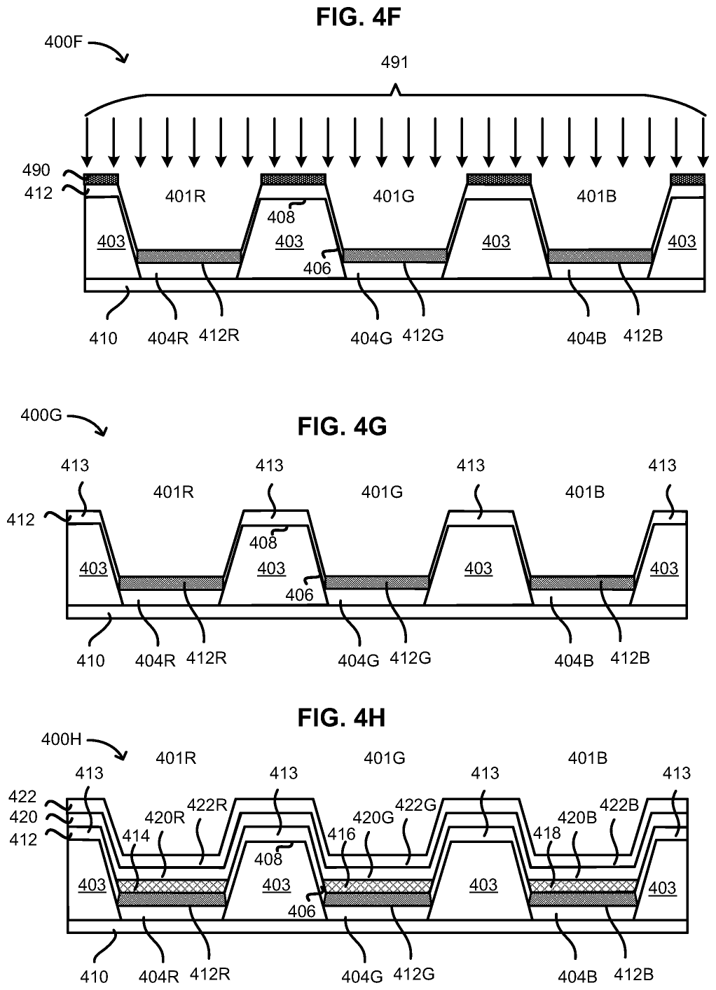

FIGS. 4A through 4H illustrate example light emitting structures 400A through 400H, respectively, processed in accordance with the actions described in the flowchart 280 of FIG. 2.

In the example light emitting structure 400A in FIG. 4A, anode electrodes 404R, 404G, and 404B are formed (e.g., deposited) in sub-pixel areas 401R, 401G, and 401B, respectively, on a substrate 410, where the sub-pixel areas 401R, 401G, and 401B are separated by bank structures 403. In the illustrated implementation, the three sub-pixel areas 401R, 401G, and 401B are used to distinguish between three different color RGB (e.g., red, green, and blue) sub-pixels. It should be understood that a display device according implementations of the present disclosure may include a two-dimensional array of the pixels each having the RGB sub-pixels.

The anode electrodes 404R, 404G, and 404B may each include the same material in the three sub-pixel areas or a different material for each sub-pixel area, and may or may not have the same thickness. The bank structures 403 include insulating materials, and are shaped to accommodate three different sub-pixels (e.g., LEDs) in the sub-pixel areas 401R, 401G, and 401B. In the present implementation, each of the bank structures 403 includes sidewalls 406 and a top portion 408.

In the example light emitting structure 400B in FIG. 4B, an HTL 412 is formed (deposited) over the light emitting structure 400A shown in FIG. 4A. In the present implementation, the HTL 412 is a continuous layer covering the bank structures 403 as well as the anode electrodes 404R, 404G, and 404B. As shown in FIG. 4B, in each of the sub-pixel areas 401R, 401G, and 401B, a portion (e.g., portion 412R, 412G, or 412B) of the HTL 412 is formed over the corresponding one of the anode electrodes 404R, 404G, and 404B. The HTL 412 is also formed on the sidewalls 406 and the top portion 408 of each of the bank structures 403.

In the example light emitting structure 400C in FIG. 4C, a patterned photomask (e.g., a shadow mask) 485 is formed over portions of the HTL 412. The patterned photomask 485 covers the sub-pixel areas 401R, 401G, and 401B, and exposes portions of the HTL 412 on the top portions 408 of the bank structures 403. While the patterned photomask 485 is in place, the light emitting structure 400C undergoes a light treatment (e.g., a UV treatment), where the exposed portions of the HTL 412 on the top portions 408 of the bank structures 403 receive light radiation 486 (e.g., UV radiation).

In the example light emitting structure 400D in FIG. 4D, the patterned photomask 485 is removed. As a result of the light treatment, the exposed portions 413 of the HTL 412 on the bank structures 403 have altered charge transporting properties (e.g., electrical conductivity or sheet-resistance), while the charge transporting properties of the portions of the HTL 412 covered by the patterned photomask 485 remain unaffected by the light treatment. For example, the exposed portions 413 of the HTL 412 on the top portions 408 of the bank structures 403 have an increased sheet-resistance (or reduced electrical conductivity) as compared to the portions 412R, 412G, and 412B of the HTL 412 in the sub-pixel areas 401R, 401G, and 401B, respectively, that were covered by the patterned photomask 485 during the light treatment.

In the example light emitting structure 400E in FIG. 4E, EMLs 414, 416, and 418 are formed over the portions 412R, 412G, and 412B of the HTL 412, respectively. The EMLs 414, 416, and 418, in one implementation, may constitute different organic semiconductor layers or QD layers in order to create an RGB array for multi-color displays and may or may not have the same thickness. An ETL 420 is formed over the EMLs 414, 416, and 418. The ETL 420 may be a continuous layer covering the bank structures 403 as well as the sub-pixel areas 401R, 401G, and 401B. In addition, a cathode electrode layer 422 (e.g., having second electrodes 422R, 422G, and 422B) is formed over the ETL 420 thus creating three completed LED sub-pixels in the light emitting structure 400E. The cathode electrode layer 422 may be made of multiple materials, and the materials forming the cathode electrode layer 422 may or may not be continuous. In the light emitting structure 400E shown in FIG. 4E, the HTL 412 on the bank structures 403 were treated with light radiation 486 (FIG. 4C) thereby having altered charge transporting properties.

In the example light emitting structure 400F in FIG. 4F, instead of forming the patterned photomask 485 over the sub-pixel areas 401R, 401G, and 401B as shown in FIG. 4C, a patterned photomask (e.g., a shadow mask) 490 is formed over the HTL 412. The patterned photomask 490 covers portions of the HTL 412 on the top portions 408 of the bank structures 403, and exposes portions of the HTL 412 (e.g., e.g., the portions 412R, 412G, and 412B) in the sub-pixel areas 401R, 401G, and 401B. While the patterned photomask 490 is in place, the light emitting structure 400F undergoes a light treatment (e.g., a UV treatment), where the exposed portions of the HTL 412 in the sub-pixel areas 401R, 401G, and 401B receive light radiation 491 (e.g., UV radiation).

In the example light emitting structure 400G in FIG. 4G, the patterned photomask 490 is removed. As a result of the light treatment, the exposed portions 412R, 412G, and 412B of the HTL 412 in the sub-pixel areas 401R, 401G, and 401B, respectively, have altered charge transporting properties, while the charge transporting properties of the portions of the HTL 412 covered by the patterned photomask 490 remain unaffected by the light treatment. For example, the portions 412R, 412G, and 412B of the HTL 412 in the sub-pixel areas 401R, 401G, and 401B, respectively, have an increased electrical conductivity (or reduced sheet-resistance) as compared to the portions 413 of the HTL 412 on the top portions 408 of the bank structures 403 that were covered by the patterned photomask 490 during the light treatment.

In the example light emitting structure 400H in FIG. 4H, the EMLs 414, 416, and 418 are formed over the portions 412R, 412G, and 412B of the HTL 412, respectively. The EMLs 414, 416, and 418, in one implementation, may constitute different organic semiconductor layers or QD layers, and may or may not be the same thickness, in order to create an RGB array for multi-color displays. Also, an ETL 420 and a cathode electrode 422 are formed over the EMLs 414, 416, and 418. The ETL 420 may be a continuous layer covering the bank structures 403 as well as the sub-pixel areas 401R, 401G, and 401B. In addition, the cathode electrode layer 422 is formed over the ETL 420 thus creating three completed LED sub-pixels in the light emitting structure 400H. In the light emitting structure 400H shown in FIG. 4H, the HTL 412 in the sub-pixel areas 401R, 401G, and 401B were treated with light radiation 491 (FIG. 4F) thereby having altered charge transporting properties.

With respect to FIGS. 4A and 4H, it should be understood that the anode electrodes 404R, 404G, and 404B may comprise the same material and may or may not have the same thickness. Likewise, the portions 412R, 412G, and 412B of the HTL 412 may comprise the same material. Similarly, referring to FIGS. 4E and 4H, different portions of the ETL 420 may comprise the same material, as with the second electrode layer 422.

With respect to FIGS. 4E and 4H, as discussed above, in a preferred implementation, the EMLs 414, 416, and 418 may each comprise different organic semiconductor layers or QD layers, and may or may not have the same thickness, in order to generate an RGB multi-color display. However, in another implementation, the EMLs 414, 416, and 418 may comprise the same material.

In each of FIGS. 4A through 4H, the thickness of individual layers is preferably in the range of 1 to 150 nm, and the thickness of the second electrode layer 422 may or may not be much thicker than 150 nm. Additionally, the light radiations 486 and 491 to the HTL (e.g., first CTL 412) may be different depending on the CTL materials used, and the characteristics of those materials, such as photochemical response to UV-light.

In one implementation, after treatment with the light radiations 486 and/or 491, the electrical conductivity (or sheet resistance) of the HTL 412 is lower (or higher, related to the sheet resistance) on the portions 413 of the bank structures 403 than in the sub-pixel areas 401R, 401G, and 401B. The lower electrical conductivity (or higher sheet resistance) of the HTL 412 over the bank structures 403 prevents leakage (or cross-talking) across adjacent sub-pixels of the current percolating across the HTL 412.

The present method may be applied to a direct LED structure, where the portions 412R, 412G, and 412B of the HTL 412 may each include a hole transporting layer (HTL), a hole injecting layer (HIL) and/or an electron blocking layers (EBL). The portions 420R, 420G, and 420B of the ETL 420 may each include an electron transporting layer (ETL), an electron injecting layer (EIL) and/or a hole blocking layer (HBL).

Light exposures (e.g., UV-radiation exposures) may be carried out on the bank structures 403 (including the top portions 408), and/or in the sub-pixel areas 401R, 401G, and 401B based on the light response of a particular CTL material used. The light exposures to the HTL 412 may disrupt the planar conductivity of the HTL 412 between the RGB sub-pixels thereby substantially eliminating current leakage/cross talk across different sub-pixels.

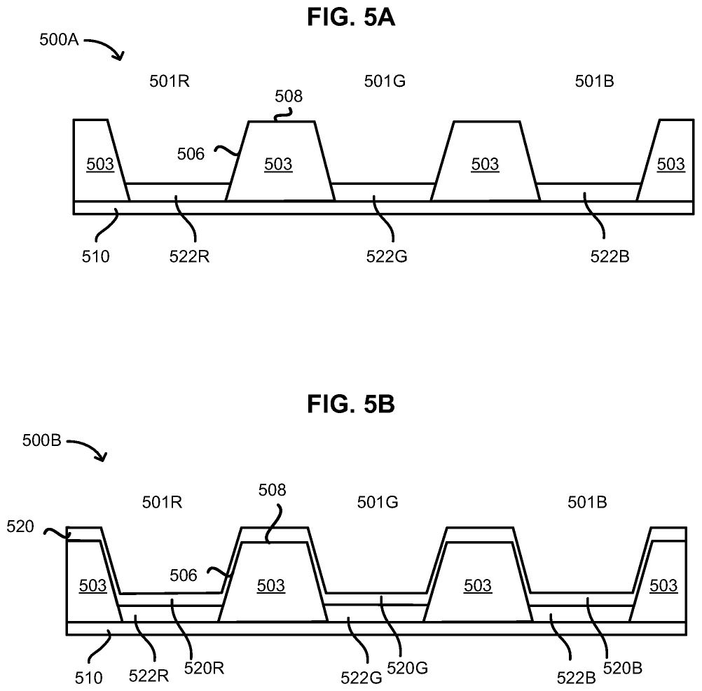

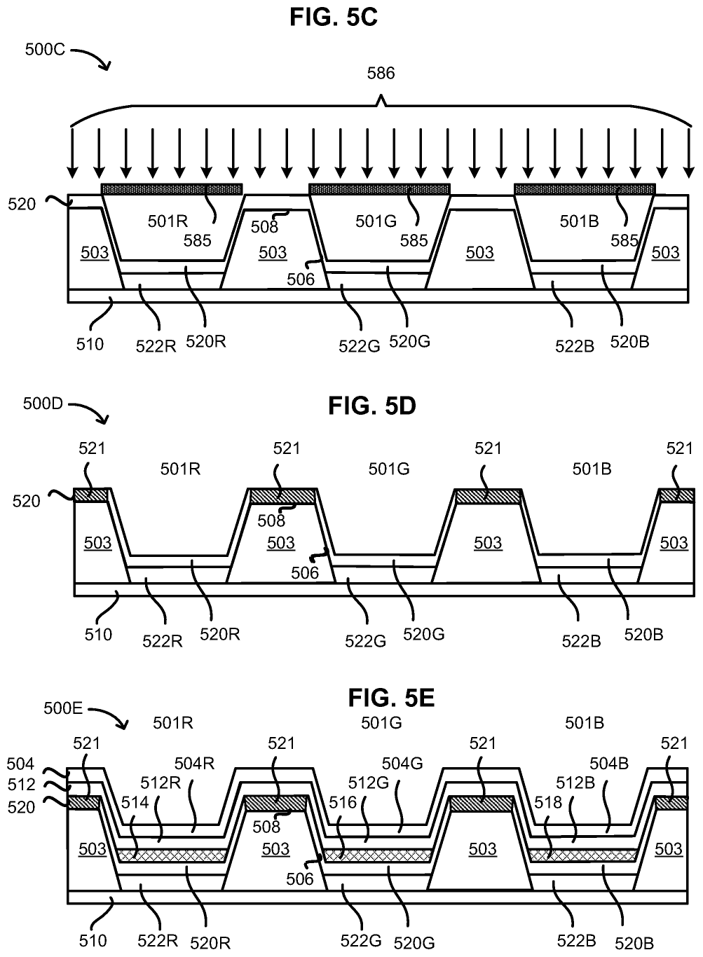

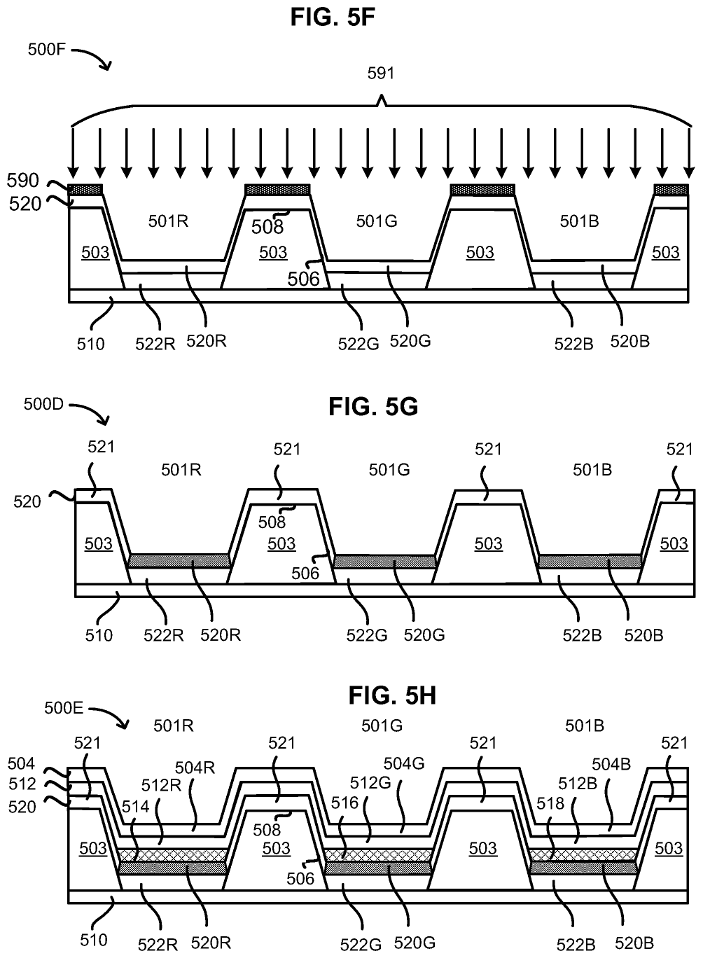

FIGS. 5A through 5H illustrate example light emitting structures 500A through 500H, respectively, processed in accordance with the actions described in the flowchart 280 of FIG. 2.

In the example light emitting structure 500A in FIG. 5A, cathode electrodes 522R, 522G, and 522B are formed (e.g., deposited) in sub-pixel areas 501R, 501G, and 501B, respectively, on a substrate 510, where the sub-pixel areas 501R, 501G, and 501B are separated by bank structures 503. In the illustrated implementation, the three sub-pixel areas 501R, 501G, and 501B are used to distinguish between three different color RGB (e.g., red, green, and blue) sub-pixels. It should be understood that a display device according implementations of the present disclosure may include a two-dimensional array of the pixels each having the RGB sub-pixels.

The cathode electrodes 522R, 522G, and 522B may each include the same material, and may or may not have the same thickness in the three sub-pixel areas or a different material for each sub-pixel area. The bank structures 503 include insulating materials, and are shaped to accommodate three different sub-pixels (e.g., LEDs) in the sub-pixel areas 501R, 501G, and 501B. In the present implementation, each of the bank structures 503 includes sidewalls 506 and a top portion 508.

In the example light emitting structure 500B in FIG. 5B, an ETL 520 is formed (deposited) over the light emitting structure 500A shown in FIG. 5A. In the present implementation, the ETL 520 is a continuous layer covering the bank structures 503 as well as the cathode electrodes 522R, 522G, and 522B. As shown in FIG. 5B, in each of the sub-pixel areas 501R, 501G, and 501B, a portion (e.g., portion 520R, 520G, or 520B) of the ETL 520 is formed over the corresponding one of the cathode electrodes 522R, 522G, and 522B. The ETL 520 is also formed on the sidewalls 506 and the top portion 508 of each of the bank structures 503.

In the example light emitting structure 500C in FIG. 5C, a patterned photomask (e.g., a shadow mask) 585 is formed over portions of the ETL 520. The patterned photomask 585 covers the sub-pixel areas 501R, 501G, and 501B, and exposes portions of the ETL 520 on the top portions 508 of the bank structures 503. While the patterned photomask 585 is in place, the light emitting structure 500C undergoes a light treatment (e.g., a UV treatment), where the exposed portions of the ETL 520 on the top portions 508 of the bank structures 503 receive light radiation 586 (e.g., UV radiation).

In the example light emitting structure 500D in FIG. 5D, the patterned photomask 585 is removed. As a result of the light treatment, the exposed portions 521 of the ETL 520 on the bank structures 503 have altered charge transporting properties (e.g., electrical conductivity or sheet-resistance), while the charge transporting properties of the portions of the ETL 520 covered by the patterned photomask 585 remain unaffected by the light treatment. For example, the exposed portions 521 of the ETL 520 on the top portions 508 of the bank structures 503 have an increased sheet-resistance (or reduced electrical conductivity) as compared to the portions 520R, 520G, and 520B of the ETL 520 in the sub-pixel areas 501R, 501G, and 501B, respectively, that were covered by the patterned photomask 585 during the light treatment.

In the example light emitting structure 500E in FIG. 5E, EMLs 514, 516, and 518 are formed over the portions 520R, 520G, and 520B of the ETL 520, respectively. The EMLs 514, 516, and 518, in one implementation, may constitute different organic semiconductor layers or QD layers, and may or may not have the same thickness, in order to create an RGB array for multi-color displays. An HTL 512 is formed over the EMLs 514, 516, and 518. The HTL 512 may be a continuous layer covering the bank structures 503 as well as the sub-pixel areas 501R, 501G, and 501B. In addition, an anode electrode layer 504 (e.g., having second electrodes 504R, 504G, and 504B) is formed over the HTL 512 thus creating three completed LED sub-pixels in the light emitting structure 500E. The anode electrode layer 504 may or may not be composed of multiple layers, and the layers may or may not be continuous across the three second electrodes 504R, 504G, and 504B. In the light emitting structure 500E shown in FIG. 5E, the ETL 520 on the bank structures 503 were treated with light radiation 586 (FIG. 5C) thereby having altered charge transporting properties.

In the example light emitting structure 500F in FIG. 5F, instead of forming the patterned photomask 585 over the sub-pixel areas 501R, 501G, and 501B as shown in FIG. 5C, a patterned photomask (e.g., a shadow mask) 590 is formed over the ETL 520. The patterned photomask 590 covers portions of the ETL 520 on the top portions 508 of the bank structures 503, and exposes portions of the ETL 520 (e.g., e.g., the portions 520R, 520G, and 520B) in the sub-pixel areas 501R, 501G, and 501B. While the patterned photomask 590 is in place, the light emitting structure 500F undergoes a light treatment (e.g., a UV treatment), where the exposed portions of the ETL 520 in the sub-pixel areas 501R, 501G, and 501B receive light radiation 591 (e.g., UV radiation).

In the example light emitting structure 500G in FIG. 5G, the patterned photomask 590 is removed. As a result of the light treatment, the exposed portions 520R, 520G, and 520B of the ETL 520 in the sub-pixel areas 501R, 501G, and 501B, respectively, have altered charge transporting properties, while the charge transporting properties of the portions of the ETL 520 covered by the patterned photomask 590 remain unaffected by the light treatment. For example, the portions 520R, 520G, and 520B of the ETL 520 in the sub-pixel areas 501R, 501G, and 501B, respectively, have an increased electrical conductivity (or reduced sheet-resistance) as compared to the portions 521 of the ETL 520 on the top portions 508 of the bank structures 503 that were covered by the patterned photomask 590 during the light treatment.

In the example light emitting structure 500H in FIG. 5H, the EMLs 514, 516, and 518 are formed over the portions 520R, 520G, and 520B of the ETL 520, respectively. The EMLs 514, 516, and 518, in one implementation, may constitute different organic semiconductor layers or QD layers, and may or may not have the same thickness, in order to create an RGB array for multi-color displays. Also, an HTL 512 and a plurality of anode electrodes 504 are formed over the EMLs 514, 516, and 518. The HTL 512 may be a continuous layer covering the bank structures 503 as well as the sub-pixel areas 501R, 501G, and 501B. In addition, an anode electrode layer 504 is formed over the HTL 512 thus creating three completed LED sub-pixels in the light emitting structure 500H. The anode electrode layer 504 may or may not be composed of multiple layers, and the layers may or may not be continuous across the three second electrodes 504R, 504G, and 504B. In the light emitting structure 500H shown in FIG. 5H, the ETL 520 in the sub-pixel areas 501R, 501G, and 501B were treated with light radiation 591 (FIG. 5F) thereby having altered charge transporting properties.

With respect to FIGS. 5A and 5H, it should be understood that the cathode electrodes 504R, 504G, and 504B may comprise the same material, and may or may not have the same thickness. Likewise, the portions 512R, 512G, and 512B of the HTL 512 may comprise the same material. Similarly, referring to FIGS. 5E and 5H, different portions of t, he ETL 520 may comprise the same material, as with the cathode electrode layer 522.

With respect to FIGS. 5E and 5H, as discussed above, in a preferred implementation, the EMLs 514, 516, and 518 may each comprise different organic semiconductor layers or QD layers, and may or may not all have the same thickness, in order to generate an RGB multi-color display. However, in another implementation, the EMLs 514, 516, and 518 may comprise the same material, and may or may not all have the same thickness.

In each of FIGS. 5A through 5H, the thickness of individual layers is preferably in the range of 1 to 150 nm. Additionally, the light radiations 586 and 591 to the ETL (e.g., ETL 520) may be different depending on the CTL materials used, and the characteristics of those materials, such as photochemical response to UV-light.

In one implementation, after treatment with the light radiations 586 and/or 591, the electrical conductivity (or sheet resistance) of the ETL 520 is lower (or higher, related to the sheet resistance) on the portions 521 of the bank structures 503 than in the sub-pixel areas 501R, 501G, and 501B. The lower electrical conductivity (or higher sheet resistance) of the ETL 520 over the bank structures 503 prevents leakage (or cross-talking) across adjacent sub-pixels of the current percolating across the ETL 520.

Still referring to FIGS. 5A through 5H, the present method may also be applied to an inverted LED structure, where the second electrodes 522R, 522G, and 522B are cathode electrodes, the portions 520R, 520G, and 5220B of the second CTL 520 may each include an ETL, an EIL and/or an HBL. The portions 512R, 512G, and 512B of the first CTL 512 may each include an HTL, an HIL, and/or an EBL. The first electrode layer 504 is an anode electrode layer.

Light exposures (e.g., UV-radiation exposures) may be carried out on the bank structures 503 (including the top portions 508), and/or in the sub-pixel areas 501R, 501G, and 501B based on the light response of a particular CTL material used. The light exposures to the ETL 520 may disrupt the planar conductivity of the ETL 520 between the RGB sub-pixels thereby substantially eliminating current leakage/cross talk across different sub-pixels.

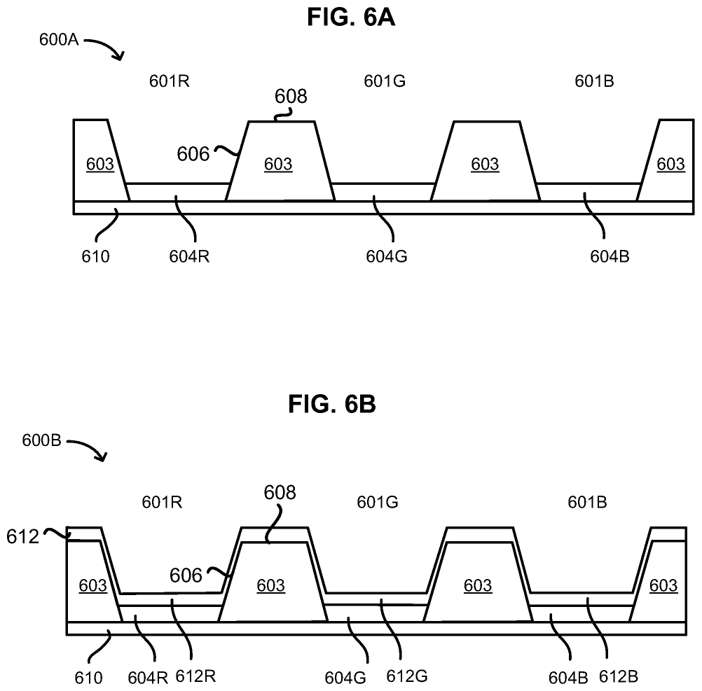

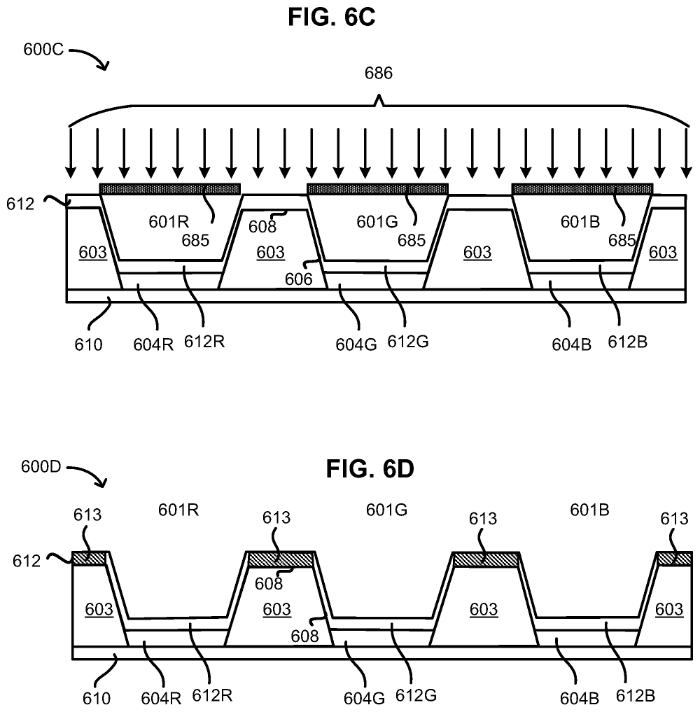

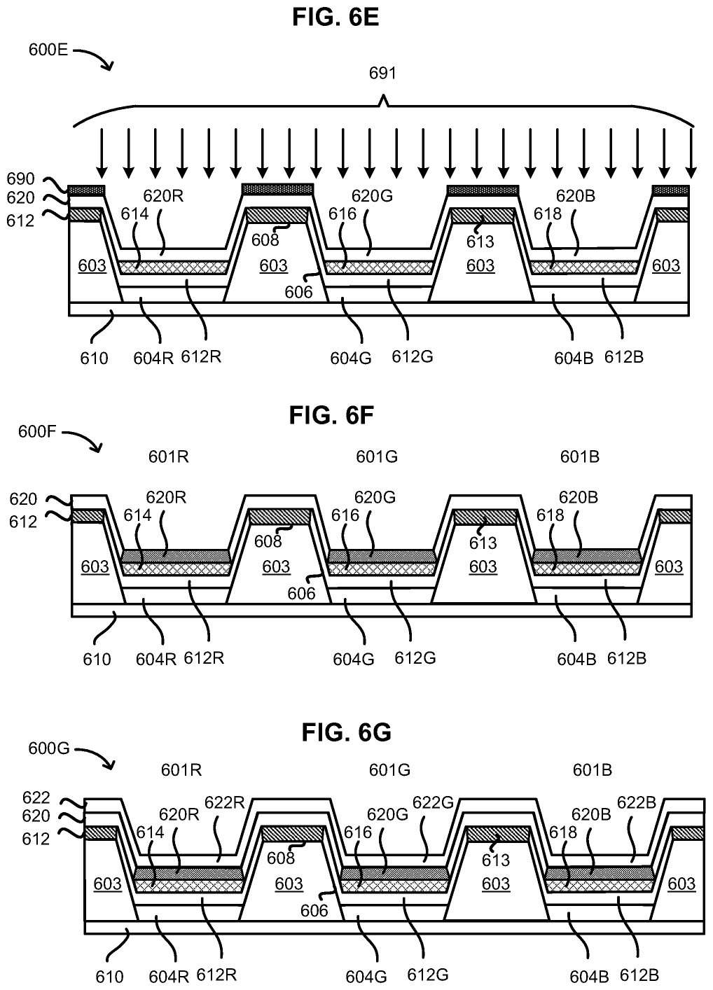

FIGS. 6A through 6G illustrate example light emitting structures 600A through 600G, respectively, processed in accordance with the actions described in the flowchart 280 of FIG. 2.

In the example light emitting structure 600A in FIG. 6A, anode electrodes 604R, 604G, and 604B are formed (e.g., deposited) in sub-pixel areas 601R, 601G, and 601B, respectively, on a substrate 610, where the sub-pixel areas 601R, 601G, and 601B are separated by bank structures 603. In the illustrated implementation, the three sub-pixel areas 601R, 601G, and 601B are used to distinguish between three different color RGB (e.g., red, green, and blue) sub-pixels. It should be understood that a display device according implementations of the present disclosure may include a two-dimensional array of the pixels each having the RGB sub-pixels.

The anode electrodes 604R, 604G, and 604B may each include the same material, and may or may not be the same thickness in the three sub-pixel areas or a different material for each sub-pixel area. The bank structures 603 include insulating materials, and are shaped to accommodate three different sub-pixels (e.g., LEDs) in the sub-pixel areas 601R, 601G, and 601B. In the present implementation, each of the bank structures 603 includes sidewalls 606 and a top portion 608.

In the example light emitting structure 600B in FIG. 6B, an HTL 612 is formed (deposited) over the light emitting structure 600A shown in FIG. 6A. In the present implementation, the HTL 612 is a continuous layer covering the bank structures 603 as well as the anode electrodes 604R, 604G, and 604B. As shown in FIG. 6B, in each of the sub-pixel areas 601R, 601G, and 601B, a portion (e.g., portion 612R, 612G, or 612B) of the HTL 612 is formed over the corresponding one of the anode electrodes 604R, 604G, and 604B. The HTL 612 is also formed on the sidewalls 606 and the top portion 608 of each of the bank structures 603.

In the example light emitting structure 600C in FIG. 6C, a patterned photomask (e.g., a shadow mask) 685 is formed over portions of the HTL 612. The patterned photomask 685 covers the sub-pixel areas 601R, 601G, and 601B, and exposes portions of the HTL 612 on the top portions 608 of the bank structures 603. While the patterned photomask 685 is in place, the light emitting structure 600C undergoes a light treatment (e.g., a UV treatment), where the exposed portions of the HTL 612 on the top portions 608 of the bank structures 603 receive light radiation 686 (e.g., UV radiation).

In the example light emitting structure 600D in FIG. 6D, the patterned photomask 685 is removed. As a result of the light treatment, the exposed portions 613 of the HTL 612 on the bank structures 603 have altered charge transporting properties (e.g., electrical conductivity or sheet-resistance), while the charge transporting properties of the portions of the HTL 612 covered by the patterned photomask 685 remain unaffected by the light treatment. For example, the exposed portions 613 of the HTL 612 on the top portions 608 of the bank structures 603 have an increased sheet-resistance (or reduced electrical conductivity) as compared to the portions 612R, 612G, and 612B of the HTL 612 in the sub-pixel areas 601R, 601G, and 601B, respectively, that were covered by the patterned photomask 685 during the light treatment.

In the example light emitting structure 600E in FIG. 6E, EMLs 614, 616, and 618 are formed over the portions 612R, 612G, and 612B of the HTL 612, respectively. The EMLs 614, 616, and 618, in one implementation, may constitute different organic semiconductor layers or QD layers, and may or may not have the same thickness between portions 612R, 612G, 612B, in order to create an RGB array for multi-color displays. An ETL 620 is formed over the EMLs 614, 616, and 618. The ETL 620 may be a continuous layer covering the bank structures 603 as well as the sub-pixel areas 601R, 601G, and 601B. A patterned photomask (e.g., a shadow mask) 690 is formed over the ETL 620. The patterned photomask 690 covers portions of the ETL 620 on the top portions 608 of the bank structures 603, and exposes portions of the ETL 620 (e.g., e.g., the portions 620R, 620G, and 620B) in the sub-pixel areas 601R, 601G, and 601B. While the patterned photomask 690 is in place, the light emitting structure 600E undergoes a light treatment (e.g., a UV treatment), where the exposed portions of the ETL 620 in the sub-pixel areas 601R, 601G, and 601B receive light radiation 691 (e.g., UV radiation).

In the example light emitting structure 600F the patterned photomask 690 is removed. As a result of the light treatment, the exposed portions 620R, 620G, and 620B of the ETL 620 in the sub-pixel areas 601R, 601G, and 601B, respectively, have altered charge transporting properties, while the charge transporting properties of the portions of the ETL 620 covered by the patterned photomask 690 remain unaffected by the light treatment. For example, the portions 620R, 620G, and 620B of the ETL 620 in the sub-pixel areas 601R, 601G, and 601B, respectively, have an increased electrical conductivity (or reduced sheet-resistance) as compared to the portions 613 of the HTL 612 on the top portions 608 of the bank structures 603 that were covered by the patterned photomask 690 during the light treatment.

In the example light emitting structure 600G in FIG. 6G, a cathode electrode layer 622 is formed over the ETL 620 thus creating three completed LED sub-pixels in the light emitting structure 600G. In the light emitting structure 600G shown in FIG. 6G, portions of the HTL 612 on the bank structures 603, were treated with light radiation 686 (FIG. 6C) thereby having altered charge transporting properties. Additionally, portions 620R, 620G, and 620B of the ETL 620 in the sub-pixel areas 601R, 601G, and 601B were treated with light radiation 691 (FIG. 6E) thereby also having altered charge transporting properties.

With respect to FIGS. 6A and 6G, it should be understood that the anode electrodes 604R, 604G, and 604B may comprise the same material. Likewise, the portions 612R, 612G, and 612B of the HTL 612 may comprise the same material. Similarly, referring to FIGS. 6E, 6F, and 6G, different portions of the ETL 620 may comprise the same material, as with the cathode electrode layer 622 (FIG. 6G).

With respect to FIGS. 6E, 6F, and 6G, as discussed above, in a preferred implementation, the EMLs 614, 616, and 618 may each comprise different organic semiconductor layers or QD layers in order to generate an RGB multi-color display. However, in another implementation, the EMLs 614, 616, and 618 may comprise the same material, and may or may not have the same thickness.

In each of FIGS. 6A through 6G, the thickness of individual layers is preferably in the range of 1 to 150 nm. Additionally, the light radiations 686 and 691 to the HTL (e.g., HTL 612) and the ETL (e.g., ETL 620) may be different depending on the CTL materials used, and the characteristics of those materials, such as photochemical response to UV-light.

In one implementation, after treatment with the light radiations 686 and/or 691, the electrical conductivity (or sheet resistance) of the HTL 612 is lower (or higher, related to the sheet resistance) on the portions 613 of the bank structures 603 than in the sub-pixel areas 612R, 612G, and 612B. Additionally, the electrical conductivity (or sheet resistance) of the ETL 620 is lower (or higher, related to the sheet resistance) in the sub-pixel areas 620R, 620G, and 620B than on the top portions 613 of the bank structures 603. The lower electrical conductivity (or higher sheet resistance) of the HTL 612 over the bank structures 603, and the sub-pixel areas 601R, 601G, and 601B prevents leakage (or cross-talking) across adjacent sub-pixels of the current percolating across the HTL 612 and the ETL 620.

The present method may be applied to a direct LED structure, where the first electrodes 604R, 604G, and 604B are anode electrodes, the portions 612R, 612G, and 612B of the first CTL 612 may each include a hole transporting layer (HTL), a hole injecting layer (HIL) and/or an electron blocking layers (EBL). The portions 620R, 620G, and 620B of the second CTL 620 may each include an electron transporting layer (ETL), an electron injecting layer (EIL) and/or a hole blocking layer (HBL). The second electrode layer 622 is a cathode electrode layer.

The present method may also be applied to an inverted LED structure (not shown), where the electrodes 604R, 604G, and 604B are cathode electrodes, the portions 612R, 612G, and 612B of may each include an ETL, an EIL and/or an HBL. The portions 620R, 620G, and 620B may each include an HTL, an HIL, and/or an EBL, and the electrode layer 622 is an anode electrode layer.

Light exposures (e.g., UV-radiation exposures) may be carried out on the bank structures 603 (including the top portions 608), and in the sub-pixel areas 601R, 601G, and 601B based on the light response of a particular CTL material used. The light exposures to the HTL 612 and the ETL 620 may disrupt the planar conductivity of the HTL 612 and the ETL 620 between the RGB sub-pixels thereby substantially eliminating current leakage/cross talk across different sub-pixels.

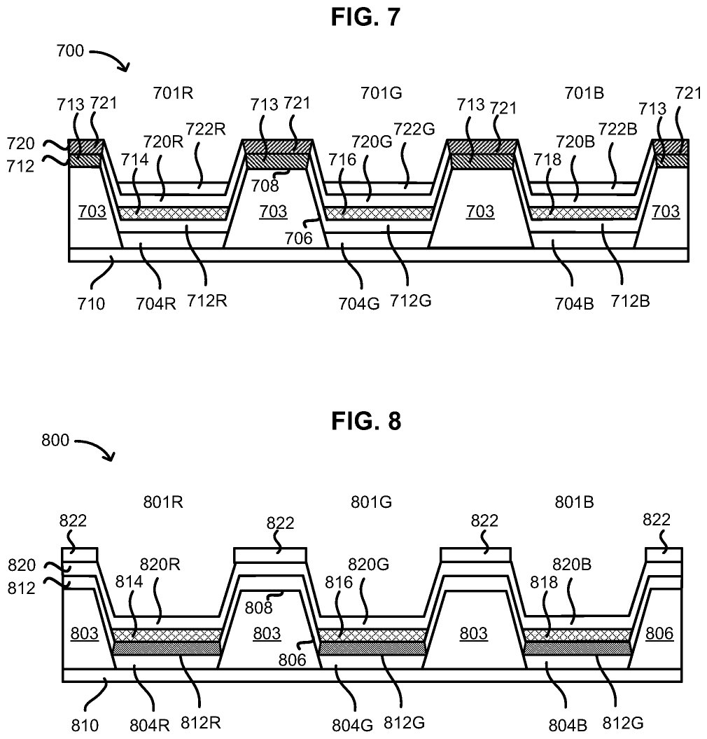

FIG. 7 illustrates an alternative light emitting structure. In FIG. 7, first electrodes 704R, 704G, and 704B are formed (e.g., deposited) in sub-pixel areas 701R, 701G, and 701B, respectively, on a substrate 710, where the sub-pixel areas 701R, 701G, and 701B are separated by bank structures 703. In the illustrated implementation, the three sub-pixel areas 701R, 701G, and 701B are used to distinguish between three different color RGB (e.g., red, green, and blue) sub-pixels. It should be understood that a display device according implementations of the present disclosure may include a two-dimensional array of the pixels each having the RGB sub-pixels.

The first electrodes 704R, 704G, and 704B may each include the same material in the three sub-pixel areas or a different material for each sub-pixel area. The bank structures 703 include insulating materials, and are shaped to accommodate three different sub-pixels (e.g., LEDs) in the sub-pixel areas 701R, 701G, and 701B. In the present implementation, each of the bank structures 703 includes sloped sidewalls 706 and a top portion 708.

A first CTL 712 is formed (deposited) over the light emitting structure 700. In the present implementation, the first CTL 712 is a continuous layer covering the bank structures 703 as well as the first electrodes 704R, 704G, and 704B. In each of the sub-pixel areas 701R, 701G, and 701B, a portion (e.g., portion 712R, 712G, or 712B) of the first CTL 712 is formed over the corresponding one of the first electrodes 704R, 704G, and 704B. The first CTL 712 is also formed on the sidewalls 706 and the top portion 708 of each of the bank structures 703.

EMLs 714, 716, and 718 are formed over the portions 712R, 712G, and 712B of the first CTL 712, respectively. The EMLs 714, 716, and 718, in one implementation, may constitute different organic semiconductor layers or QD layers, and may or may not have different thicknesses, in order to create an RGB array for high-resolution multi-color displays.

A second CTL 720 is formed (deposited) over the light emitting structure 700. In the present implementation, the second CTL 720 is a continuous layer covering the bank structures 703 as well as the EMLs 714, 716, and 718. In each of the sub-pixel areas 701R, 701G, and 701B, a portion (e.g., portion 720R, 720G, or 720B) of the second CTL 720 is formed over the corresponding one of the EMLs 714, 716, and 718. The second CTL 720 is also formed on the sidewalls 706 and the top portion 708 of each of the bank structures 703. Additionally, second electrodes 722R, 722G, and 722B have been deposited over portions 720R, 720G, and 720B of the second CTL 720, thus creating three completed LED sub-pixels in the light emitting structure 700. The second electrodes 722R, 722G, and 722B may be made of one or multiple layers, and they may or may not be continuous.

The sub-pixel areas 701R, 701G, and 701B have been covered such that exposed portions 713 of the first CTL 712 on the top portions 708 of the bank structures 703, and exposed portions 721 of the second CTL 720 on the top portions 708 of the bank structures 703 have been exposed to light radiation. As a result, both portions 713 of the first CTL 712 on the top portions 708 of the bank structures 703, and exposed portions 721 of the second CTL 720 on the top portions 708 of the bank structures 703 have altered charge transporting properties, substantially eliminating current leakage/cross talk across different sub-pixels.

FIG. 8 illustrates an alternative light emitting structure. In FIG. 8, first electrodes 804R, 804G, and 804B are formed (e.g., deposited) in sub-pixel areas 801R, 801G, and 801B, respectively, on a substrate 810, where the sub-pixel areas 801R, 801G, and 801B are separated by bank structures 803. In the illustrated implementation, the three sub-pixel areas 801R, 801G, and 801B are used to distinguish between three different color RGB (e.g., red, green, and blue) sub-pixels. It should be understood that a display device according implementations of the present disclosure may include a two-dimensional array of the pixels each having the RGB sub-pixels.

The first electrodes 804R, 804G, and 804B may each include the same material, may be made of one or multiple layers, and the layers may or may not be of different thicknesses, in the three sub-pixel areas or a different material for each sub-pixel area. The bank structures 803 include insulating materials, and are shaped to accommodate three different sub-pixels (e.g., LEDs) in the sub-pixel areas 801R, 801G, and 801B. In the present implementation, each of the bank structures 803 includes sidewalls 806 and a top portion 808.

A first CTL 812 is formed (deposited) over the light emitting structure 800. In the present implementation, the first CTL 812 is a continuous layer covering the bank structures 803 as well as the first electrodes 804R, 804G, and 804B. In each of the sub-pixel areas 801R, 801G, and 801B, a portion (e.g., portion 812R, 812G, or 812B) of the first CTL 812 is formed over the corresponding one of the first electrodes 804R, 804G, and 804B. The first CTL 812 is also formed on the sidewalls 806 and the top portion 808 of each of the bank structures 803.

The top portions 808 have been previously covered such that exposed portions 812R, 812G, and 812B of the first CTL 812 formed over the corresponding one of the first electrodes 804R, 804G, and 804B have been exposed to light radiation. As a result, the exposed portions 812R, 812G, and 812B of the first CTL 812 formed over the corresponding one of the first electrodes 804R, 804G, and 804B have altered charge transporting properties.

EMLs 814, 816, and 818 are formed over the portions 812R, 812G, and 812B of the first CTL 812, respectively. The EMLs 814, 816, and 818, in one implementation, may constitute different organic semiconductor layers or QD layers, and may or may not have different thicknesses, in order to create an RGB array for multi-color displays.

A second CTL 820 is formed has been deposited over the light emitting structure 800. In the present implementation, the second CTL 820 is a continuous layer covering the bank structures 803 as well as the EMLs 814, 816, and 818. In each of the sub-pixel areas 801R, 801G, and 801B, a portion (e.g., portion 820R, 820G, or 820B) of the second CTL 820 is formed over the corresponding one of the EMLs 814, 816, and 818. The second CTL 820 is also formed on the sidewalls 806 and the top portion 808 of each of the bank structures 803. Second electrodes 822 have been deposited over the top portion 808 of each bank 803, thus creating three completed LED sub-pixels in the light emitting structure 800. By depositing the second electrodes 822 only on the top portion 808 of each bank 803, as well as altering the charge transporting properties of exposed portions 812R, 812G, and 812B of the first CTL 812, current leakage/cross talk across different sub-pixels is substantially eliminated.

Structures and Materials

Referring to FIGS. 2A through 5G, the substrates 210, 310, 410, 510 may be made from any suitable material(s). Exemplary substrates include glass substrates and polymer substrates. More specific examples of substrate material(s) include polyimides, polyethenes, polyethylenes, polyesters, polycarbonates, polyethersulfones, polypropylenes, and/or polyether ether ketones. The substrates 101, 210, 310, 410, 510 may be produced in any suitable shape and size.

Referring to the FIGS. 3A through 8, the bank structures 303, 403, 503, 603, 703, and 803 may comprise various materials. Exemplary insulating materials may include, but are not limited to, polyimides. In some examples, the insulating material may include a surface treatment, such as for example fluorine, to modify the insulating material wetting properties. For example, the insulating material may be made hydrophilic to prevent the deposited material from sticking on the bank structures 303, 403, 503, 603, 703, and 803 and to ensure each sub-pixel is properly filled. The insulating material thus forms wells, the bottoms of which may include different electrodes (e.g., anodes) for each sub-pixel.

In the implementations as discussed above in which UV treatments are applied, the variation in the value of CTL sheet resistance (or conductivity) parameters between UV-exposed and non-UV-exposed areas may preferably be a factor of four to efficiently reduce the current leakage across sub-pixels. For example, the sheet resistance of an exposed CTL in the bank area may be four times higher than that of a non-UV-exposed CTL in the sub-pixel area to prevent current leakage when the UV exposure increases the resistance in the exposed CTL. For conductivity, the value of the exposed CTL in the bank area is four times lower than that of a non-UV-exposed CTL in the sub-pixel area, in the same case.

Regarding all implementations discussed above, HTL and ETL materials may feature a conductivity (or sheet-resistance) that changes through the light exposure (i.e. increasing or decreasing the electrical conductivity or sheet-resistance) of the material. In various implementations, HTL and ETL material may be any organic semiconductors, in which light exposure affects the carbon double bonds across the amorphous or crystalline material structure. Additionally, in some implementations, HTL and ETL materials may be any metal-oxide nanoparticles, in which the light exposure removes carbon species from the surface of the thin films to reduce oxygen-related defects and release free carriers at the boundaries and interfaces, by improving the conductivity of the thin films.

Regarding all implementations discussed above, the hole transporting layer (HTL) may include organic polymeric materials such as poly(3,4-ethylenedioxythiophene):poly (styrenesulfonate) (PEDOT:PSS), poly(9,9-dioctylfluorene-co-N-(4-sec-butylphenyl)-diphenylamine) (TFB), poly(9-vinylcarbazole) (PVK), poly(N,N′-bis(4-butylphenyl)-N,N′-bisphenylbenzidine) (poly-TPD), metal oxide materials for example V₂O₅, NiO, CuO, WO₃, MoO₃ or organic small molecule materials such as 2,3,5,6-tetrafluoro-7,7,8,8-tetracyanoquinodimethane (F4TCNQ), 1,4,5,8,9,11-hexaazatriphenylenehexacarbonitrile (HATCN), N4,N4′-Bis(4-(6-((3-ethyloxetan-3-yl)methoxy)hexyl)phenyl)-N4,N4′-diphenylbiphenyl-4,4′-diamine (OTPD), N4,N4′-Bis(4-(6-((3-ethyloxetan-3-yl)methoxy) hexyloxy)phenyl)-N4,N4′-bis(4-methoxyphenyl)biphenyl-4,4′-diamine (QUPD), and N,N′-(4,4′-(Cyclohexane-1,1-diyl)bis(4,1-phenylene))bis(N-(4-(6-(2-ethyloxetan-2-yloxy)hexyl)phenyl)-3,4,5-trifluoroaniline) (X-F6-TAPC), Copper(I) thiocyanate (CuSCN). In implementations where the HTL includes more than one layer, the materials of the respective layers may differ. The light-emitting device may include one or more additional layers, such as a hole injection layer (HIL). Exemplary materials suitable for use in an HIL include, but are not limited to, poly(3,4-ethylenedioxythiophene) polystyrene sulfonate (PEDOT:PSS), molybdenum oxide (MoO₃), a mixture of MoO3:PEDOT:PSS; V₂O₅, a mixture of PEDOT:PSS:V₂O₅, WO₃, MoO₃, 2,3,5,6-tetrafluoro-7,7,8,8-tetracyanoquinodimethane (F4TCNQ), and/or 1,4,5,8,9,11-hexaazatriphenylenehexacarbonitrile (HATCN).

Regarding all implementations discussed above, the penultimate layer that is proximate to a terminal electrode is the electron transporting layer (ETL). An ETL may consist of one or more layers and may be made from any suitable materials that are optimized to transport electrons to an emissive layer (EML). ETLs may consist of metal oxides such as ZnO, MgₓZn₁₋ₓO where 0≤x≤1, AlₓZn₁₋ₓO where 0≤x≤1, TiO₂ and ZrO₂, organic small molecules such as 2,2′,2″-(1,3,5-benzinetriyl)-tris(1-phenyl-1-H-benzimidazole) (TPBi), N4,N4′-Di(naphthalen-1-yl)-N4,N4′-bis(4-vinylphenyl)biphenyl-4,4′-diamine (VNPB), and 9,9-Bis[4-[(4-ethenylphenyl)methoxy]phenyl]-N2,N7-di-1-naphthalenyl-N2,N7-diphenyl-9H-Fluorene-2,7-diamine (VB-FNPD) and thin ionic interlayers such as 8-quinolinolato lithium (Liq.), LiF, Cs₂CO₃. Where more than one material is used, these materials will differ. Exemplary materials suitable for use in an electron injection layer include, but are not limited to, 8-quinolinolato lithium (Liq), LiF, Cs₂CO₃, Calcium (Ca), Barium (Ba), or a polyelectrolyte such as poly (ethylenimine) (PEI) or poly(ethylenimine) ethoxylated (PEIE).

Regarding some implementations discussed above, a UV wavelength ranging from 193 nm to 400 nm may be preferable. A UV exposure time ranging from 0.1 second to 1 hour may be preferable. In addition, a UV exposure intensity ranging from 0.1 mJ/cm² to 100,000 mJ/cm² may be preferable.

Exposing the bank structures, or the pixel areas (A, B, and C), obtains several advantages: A three color display can be produced using the disclosed structure and method; the special UV-photolithography across the different pixels aimed to modify the conductivity in exposed areas will hinder the current problem of leaking/cross-talking across adjacent pixels; the method is compatible with several solution-processed fabrication processes, such as spin-coating, blade-coating, spray coating and ink-jet dispensing coating, and it eliminates the requirement of adjusting layer thicknesses or disrupting the LED structure; the method is compatible with UV-patterned QLEDs; and the spatial UV-photolithography may also modify the surface energy of the UV-light exposed area promoting spatial confinement of the deposited solution within bank structure, and at the same time hindering the coffee-ring effect.

What is claimed is:

1. A light emitting device comprising:
a sub-pixel stack in a sub-pixel region, the sub-pixel stack comprising at least:
a first electrode;
a second electrode;
an emissive layer between the first electrode and the second electrode;
a first charge transporting or injecting layer between the emissive layer and the first electrode;
a second charge transporting or injecting layer between the emissive layer and the second electrode;
a bank in a bank region, the bank surrounding the sup-pixel stack;
wherein at least one of the first charge transporting or injecting layer and the second charge transporting or injecting layer is formed in the sub-pixel region and the bank region;
wherein an electrical resistance of the at least one of the first charge transporting or injecting layer and the second charge transporting or injecting layer in the bank region is higher than the sub-pixel region.

2. The light-emitting device of claim 1, wherein the first electrode is an anode, and the first charge transporting or injecting layer is a hole transporting or injecting layer.

3. The light-emitting device of claim 2, wherein the second electrode is a cathode, and the second charge transporting or injecting layer is an electron transporting or injecting layer.

4. The light-emitting device of claim 1, wherein the first electrode is a cathode, and the first charge transporting or injecting layer is an electron transporting or injecting layer.

5. The light-emitting device of claim 4, wherein the second electrode is an anode, and the second charge transporting or injecting layer is a hole transporting or injecting layer.

6. The light-emitting device of claim 1, wherein the at least one of the first charge transporting or injecting layer and the second charge transporting or injecting layer in the bank region has an increased electrical resistance than in the sub-pixel region, and the emissive layer is a solution-processed emissive layer having quantum dots.

7. The light-emitting device of claim 1, wherein the at least one of the first charge transporting or injecting layer and the second charge transporting or injecting layer comprises at least one organic semiconductor material having an amorphous or crystalline structure that is modifiable by light exposure.

8. The light-emitting device of claim 1, wherein the at least one of the first charge transporting or injecting layer and the second charge transporting or injecting layer comprises metal-oxide nanoparticles.

9. A light emitting structure comprising:
a substrate;
a plurality of sub-pixel structures over the substrate;
wherein at least one of the plurality of sub-pixel structures is formed in a sub-pixel region surrounded by a bank in a bank region, and the at least one of the plurality of sub-pixel structures includes:
a first electrode;
a second electrode;
an emissive layer between the first electrode and the second electrode;
a first charge transporting or injecting layer between the emissive layer and the first electrode;
a second charge transporting or injecting layer between the emissive layer and the second electrode;
wherein at least one of the first charge transporting or injecting layer and the second charge transporting or injecting layer is formed in the sub-pixel region and the bank region;
wherein an electrical resistance of the at least one of the first charge transporting or injecting layer and the second charge transporting or injecting layer in the bank region is higher than the sub-pixel region.

10. The light-emitting structure of claim 9, wherein the first electrode is an anode, and the first charge transporting or injecting layer is a hole transporting or injecting layer.

11. The light-emitting structure of claim 10, wherein the second electrode is a cathode, and the second charge transporting or injecting layer is an electron transporting or injecting layer.

12. The light-emitting structure of claim 9, wherein the first electrode is a cathode, and the first charge transporting or injecting layer is an electron transporting or injecting layer.

13. The light-emitting structure of claim 12, wherein the second electrode is an anode, and the second charge transporting or injecting layer is a hole transporting or injecting layer.

14. The light-emitting structure of claim 9, wherein the at least one of the first charge transporting or injecting layer and the second charge transporting or injecting layer in the bank region has an increased electrical resistance in the sub-pixel region.

15. The light-emitting structure of claim 14, further comprising a light-spatial modified grid to reduce current leakage across the sub-pixel regions.

16. The light-emitting structure of claim 9, wherein the at least one of the first charge transporting or injecting layer and the second charge transporting or injecting layer comprises at least one organic semiconductor material having an amorphous or crystalline structure that is modifiable by light exposure.

17. A method of manufacturing a light emitting device, the method comprising:
forming a plurality of first electrodes in a plurality of sub-pixel areas on a substrate, the plurality of sub-pixel regions being separated by a plurality of banks;
forming a first charge transporting or injecting layer on the plurality of first electrodes and the plurality of banks;
forming and patterning a photomask over the first charge transporting or injecting layer, and subjecting exposed portions of the first charge transporting or injecting layer to an ultraviolet (UV) exposure;
removing the photomask;
forming an emissive layer (EML), a second charge transporting or injecting layer, and a plurality of second electrodes over the first charge transporting or injecting layer;
wherein the exposed portions of the first charge transporting or injecting layer have an altered electrical resistance than masked regions of the first charge transporting or injecting layer after the UV exposure.

18. The method of claim 17, wherein the photomask is patterned to cover a plurality of bank regions and expose a plurality of sub-pixel regions such that the first charge transporting or injecting layer in the plurality of bank regions has an increased electrical resistance than in the plurality of sub-pixel regions after the UV exposure.

19. The method of claim 17, wherein the photomask is patterned to cover a plurality of sub-pixel regions and expose a plurality of bank regions such that the first charge transporting or injecting layer in the plurality of sub-pixel regions has a reduced electrical resistance than in the plurality of bank regions after the UV exposure.

20. The method of claim 17, further comprising:
forming and patterning another photomask over the second charge transporting or injecting layer, and subjecting exposed portions of the second charge transporting or injecting layer to another UV exposure;
wherein the exposed portions of the second charge transporting or injecting layer have an altered electrical resistance than masked regions of the second charge transporting or injecting layer after the another UV exposure.
